(19) United States
(12) Patent Application Publication
(10) Pub. No.: US 2012/0161779 A1
(43) Pub. Date: Jun. 28, 2012

(54) DISCHARGE DEVICE AND TEST SYSTEM HAVING THE SAME

(75) Inventors: Jiau-Cheng Shiau, Taipei City (TW); Chia-Ming Chen, New Taipei City (TW)

(73) Assignee: Test Research, Inc., Taipei City (TW)

(21) Appl. No.: 13/048,572

(22) Filed: Mar. 15, 2011

(30) Foreign Application Priority Data
Dec. 27, 2010 (TW) 099146157

(51) Int. Cl. G01R 31/02; H99Z 99/00

(52) U.S. Cl. 324/537; 361/437

(57) ABSTRACT

A discharge device and a test system having the same are provided. The test system comprises at least one power supply module, a test instrument and a discharge device. The power supply module supplies power to a device under test. The test instrument is connected to the device under test. The test instrument performs a plurality of on-power test procedures on the device under test. The discharge device comprises at least one first constant current discharge unit disposed in the test instrument, at least one second constant current discharge unit disposed in the power supply module and a control module. The control module controls the first and the second constant current discharge units to drain a constant current from the device under test and the power supply module to perform a discharge process when each one of the on-power test procedures is finished.

### RELATED APPLICATIONS

This application claims priority to Taiwan Application Serial Number 099146157, filed Dec. 27, 2010, which is herein incorporated by reference.

### BACKGROUND

1. Technical Field

The present disclosure relates to a test system of an electronic device. More particularly, the present disclosure relates to a discharge device and a test system having the same.

2. Description of Related Art

There are off-power test procedures and on-power test procedures during the test flow of the electronic devices. The on-power test procedures often take half of the time of the test flow since a discharge process is performed when each on-power test procedure is finished. The discharge process makes sure that the electrical charges remain in the device under test is not large. When the power turns on in the next on-power test procedure, the large electrical charges remain in the device under test could generate a large current that may do harm to the device under test. Hence, the discharge process has to be performed when each on-power test procedure is finished. If it takes more time to perform the discharge process, the total time of the test flow will become longer.

In a conventional design, a plurality of resistors having different resistive values are adapted to perform the discharge process. A control mechanism is used to keep calculating the voltage of the device under test and select one of the resistors having the appropriate resistive value is selected to perform the discharge process on the device under test. The value of the discharge current can thus be controlled within a reasonable range. However, such a design is not able to control the discharge current precisely. It's easy to keep the discharge current at a low level such that the discharge rate is too low.

Accordingly, what is needed is a discharge device and a test system having the same to accomplish a fast discharge mechanism to shorten the time of the test flow. The present disclosure addresses such a need.

### SUMMARY

An aspect of the present disclosure is to provide a discharge device adapted in a test system. The discharge device comprises at least one constant current discharge unit and a control module. The constant current discharge unit is disposed in at least one power supply module or a test instrument of the test system. The control module controls the constant current discharge unit to drain a constant current from the device under test through the test instrument or from the power supply module to perform a discharge process when any one of the on-power test procedures is finished.

Another aspect of the present disclosure is to provide a test system. The test system comprises at least one power supply module, a test instrument and a discharge device. The power supply module supplies power to a device under test. The test instrument is connected to the device under test to perform a plurality of on-power test procedures on the device under test. The discharge device comprises at least one first constant current discharge unit, at least one second constant current discharge unit and a control module. The first constant current discharge unit is disposed in the test instrument. The second constant current discharge unit is disposed in the power supply module. The control module controls the first and the second constant current discharge units to drain a constant current from the device under test and the power supply module respectively to perform a discharge process when any one of the on-power test procedures is finished.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a block diagram of a test system in an embodiment of the present disclosure;

FIG. 2 is a detail diagram of the test instrument in FIG. 1 in an embodiment of the present disclosure;

FIG. 3 is a detail diagram of the test instrument and the discharge device disposed therein of an embodiment of the present disclosure;

FIG. 4 is a diagram of the resistor switch module of an embodiment of the present disclosure;

FIG. 5 is a more detailed diagram of the power supply modules depicted in FIG. 1 in an embodiment of the present disclosure;

FIG. 6A is a flow chart of the discharge process when the resistor switch technique is adapted;

FIG. 6B is a diagram of the relation of the voltage and the time during the discharge process depicted in FIG. 6A;

FIG. 7A is a flow chart of the discharge process when the discharge device is adapted; and

FIG. 7B is a diagram of the relation of the voltage and the time during the discharge process depicted in FIG. 7A.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

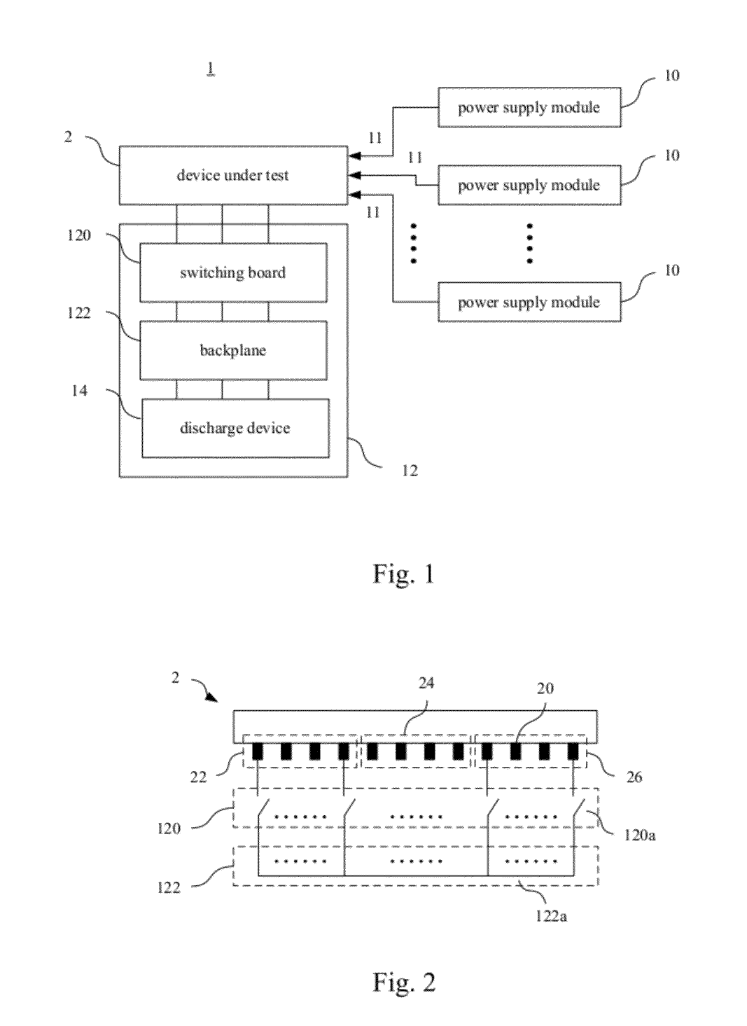

Please refer to FIG. 1. FIG. 1 is a block diagram of a test system 1 in an embodiment of the present disclosure. The test system 1 comprises power supply modules 10, a test instrument 12 and a discharge device 14.

The power supply modules 10 supply power 11 to a device under test 2. The number of the power supply modules 10 can be varied in different embodiments. The test instrument 12 is connected to the device under test 2. After the power supply modules 10 supply the power 11 to the device under test 2, the test instrument 12 performs a test flow including a plurality of on-power test procedures on the device under test 2. The test instrument 12 comprises a switching board 120 and a backplane 122.

Please refer to FIG. 2. FIG. 2 is a detail diagram of the test instrument 12 in an embodiment of the present disclosure. The switching board 120 of the test instrument 12 comprises a relay matrix having a plurality of relays 120a. The backplane 122 comprises a system bus 122a. The relay matrix of the switching board 120 is connected to the pins 20 of the device under test 2. If one of the relays 120a corresponding to a specific pin 20 is closed, the system bus 122a can be substantially electrically connected to this specific pin 20. The pins 20 can be categorized into different first pin groups 22 and 24 corresponding to different logic levels. For example, the pins 20 categorized to the first pin groups 22 are driven by the power with a logic level of 1.8 volt, and the pins 20 categorized to the second pin groups 24 are driven by the power with a logic level of 3.3 volt. In an embodiment, parts of the pins 20 are further categorized to a second pin group 26 having a negative logic level.

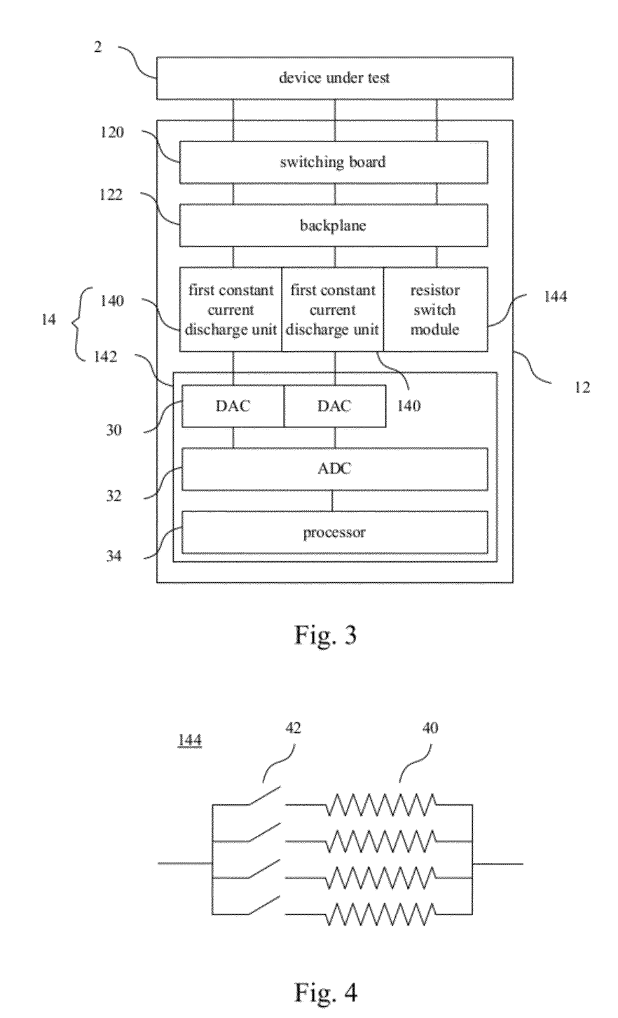

In the present embodiment, the discharge device 14 is disposed in the test instrument 12. Please refer to FIG. 3 at the same time. FIG. 3 is a detail diagram of the test instrument 12 and the discharge device 14 disposed therein of an embodiment of the present disclosure. The discharge device 14 comprises first constant current discharge units 140 and a control module 142. The first constant current discharge units 140 are connected to the pins 20 of the device under test 2 through the system bus 122a and the relays 120a of the relay matrix depicted in FIG. 2. Therefore, when the relays 120a are closed, the first constant current discharge units 140 can be substantially electrically connected to the pins 20 of the first pin group 22 or the first pin group 24 through the system bus 122a.

In an embodiment, the first constant current discharge units 140 are floating zero volt active loads. Each floating zero volt active loads functions as a constant current source to drain a current, where the value of the current is controlled by the control module 142. Therefore, when each test procedure in the test flow is finished, the control module 142 can control the first constant current discharge units 140 drain a constant current from the pins 20 of the device under test 2 through the system bus 122a and the relay matrix of the test instrument 12 to perform a discharge process to release the electrical charges remaining in the device under test 2. In the present embodiment, the number of the first constant current discharge units 140 is two such that the first constant current discharge units 140 are respectively connected to the first pin groups 22 and 24 having different logic levels as described above. Hence, the first pin groups 22 and 24 having different logic levels can be discharged through different first constant current discharge units 140 in parallel during the discharge process. In other embodiments, the number of the first constant current discharge units 140 can be adjusted according to the number of the first pin groups.

In the present embodiment, the control module 142 comprises digital to analog converters (DAC) 30, an analog to digital converter (ADC) 32 and a processor 34. The digital to analog converter 30 and the analog to digital converter 32 can retrieve value of the voltage of the device under test 2 and further converts the value of the voltage to a format that the processor 34 is able to read. Hence, the processor 34 can monitor the voltage of the device under test 2 during the discharge process. In general, the voltage of the device under test 2 keeps decreasing due to the discharge current drained by the first constant current discharge units 140 from the device under test 2. The processor 34 can be programmed such that when the voltage of the device under test 2 decreases to a value not larger than a specific level, the processor 34 determines that the electrical charge remaining in the device under test 2 is not able to do harm to the device under test 2 in the next on-power test procedure and stops the operation of the first constant current discharge units 140 to end the discharge process to allow the performance of the next on-power test procedure. In another embodiment, the discharge process can also be performed until the voltage on the device under test 2 becomes zero due to the characteristic of the floating zero volt active loads.

Therefore, there is no need to perform complex calculating process to make the discharge current maintain at a constant level with the use of the first constant current discharge units 140 to perform a fast discharge mechanism. Furthermore, the first constant current discharge units 140 can be adapted to the pin groups having different logic levels to perform the discharge process in parallel to speed up the discharge process.

In an embodiment, the pin group with negative logic level (e.g. the second pin group 26 depicted in FIG. 2) can also be discharged by the first constant current discharge units 140. However, due to the polarity problem brought by the negative logic level, a resistor switch module 144 can be used to discharge the pin group with negative logic level instead in an embodiment to avoid the polarity problem that may be generated when the floating zero volt active load is adapted. Please refer to FIG. 4. FIG. 4 is a diagram of the resistor switch module 144 of an embodiment of the present disclosure. The two ends of the resistor switch module 144 can be switched such that one end is electrically connected to the backplane 122 depicted in FIG. 3 and the other end is electrically connected to a ground potential. A plurality of resistors 40 having different resistive values are disposed in the resistor switch module 144 such that a switch 42 is able to make the resistor 40 having the appropriate value to be connected to the backplane 122 and the ground potential to discharge the device under test 2. When the value of voltage of the device under test 2 drops to a predetermined level due to the discharge process, a corresponding resistor 40 with lower resistive value is selected to keep the discharge current within a reasonable range.

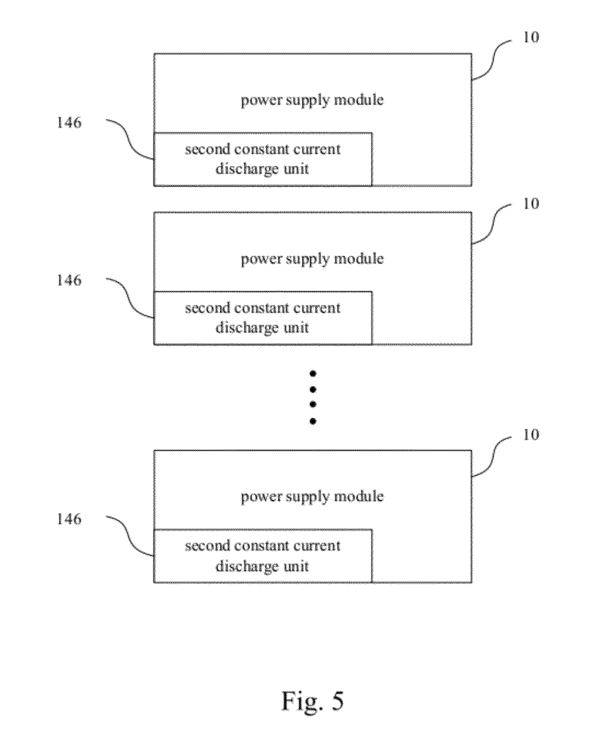

Please refer to FIG. 5. FIG. 5 is a more detailed diagram of the power supply modules 10 depicted in FIG. 1 in an embodiment of the present disclosure. In the present embodiment, in addition to the part disposed in the test instrument 12, the discharge device 14 further comprises second constant current discharge units 146 disposed in the power supply modules 10.

In an embodiment, the second constant current discharge units 146 are floating zero volt active loads as well, just like the first constant current discharge units 140. The power supply modules 10 stop supplying power 11 to the device under test 2 when the on-power test procedure is finished. However, there are still electrical charges remaining in the power supply modules 10. Consequently, the second constant current discharge units 146 can act as constant sources to drain currents from the power supply modules 10 to perform the discharge process. Similarly, the value of the current drained by the second constant current discharge units 146 can be controlled by the control module 142 depicted in FIG. 3.

Furthermore, the control module 142 can monitor the value of the voltage of the power supply modules 10 as well. In general, the voltage of the power supply modules 10 keeps decreasing due to the discharge current drained by the second constant current discharge units 146 from the power supply modules 10. The processor 34 can be programmed such that when the voltage of the power supply modules 10 decreases to a value not larger than a specific level, the processor 34 determines that the electrical charge remaining in the power supply modules 10 is not able to do harm to the device under test 2 or the power supply modules 10 in the next on-power test procedure and stops the operation of the second constant current discharge units 146 to end the discharge process to allow the performance of the next on-power test procedure. It's noticed that the control module 142 can control the first constant current discharge units 140 and the second constant current discharge units 146 with the same control mechanism or can control the first constant current discharge units 140 and the second constant current discharge units 146 with different control mechanisms. When using different control mechanisms, the control module 142 can make the first constant current discharge units 140 and the second constant current discharge units 146 drain different values of constant current and/or determine the end of the discharge process with different reference voltage levels.

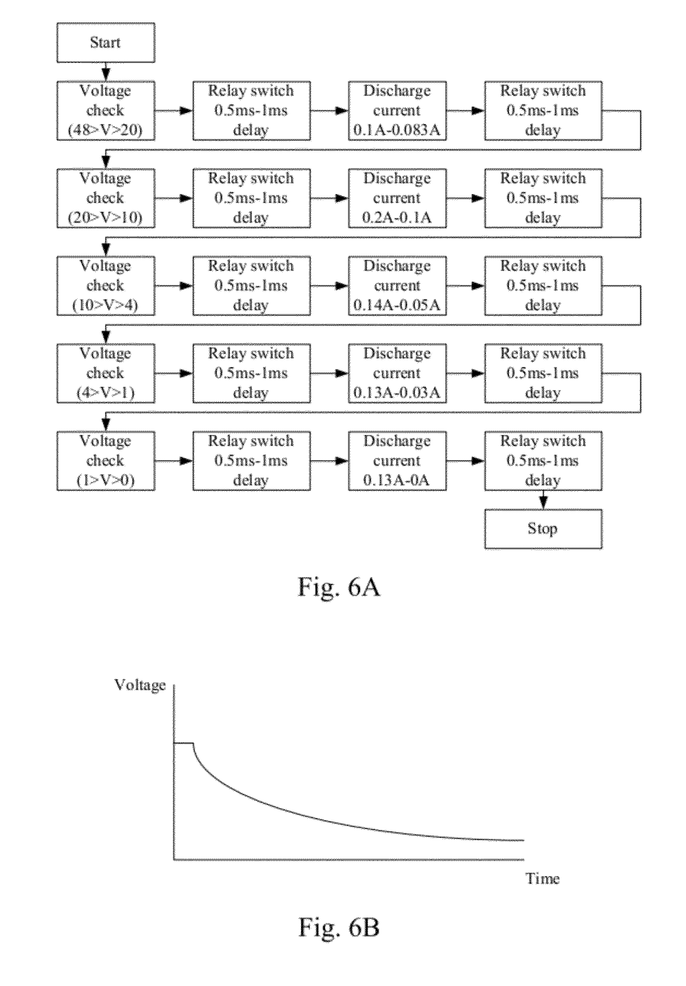

When a capacitor (coupled to the pins 20 described above or the power supply modules 10) needs to be discharged, a calculating process is necessary to determine the appropriate resistor used to discharge according to the voltage value when only the resistor switch technique is adapted to discharge the device under test 2. Please refer to FIG. 6A. FIG. 6A is a flow chart of the discharge process when the resistor switch technique is adapted. For example, when the voltage of the capacitor that needs to be discharged is 24 volt, and the capacitance of the same is 100 uF, the voltage intervals that makes the resistor switch module switches the resistors are 48-20 volt, 20-10 volt, 10-4 volt, 4-1 volt and 1-0 volt, then there will be ten times of the switching of the resistors during the discharge process, where each time of the switching of the resistors takes 0.5 ms to 1 ms. Further, the decrease of the voltage is a non-linear process as depicted in FIG. 6B due to the non-constant discharge current. If the average discharge current is 0.105 A, the total discharge time is (capacitance×voltage)/(average current), which is (100×24)/0.105=22.85 ms.

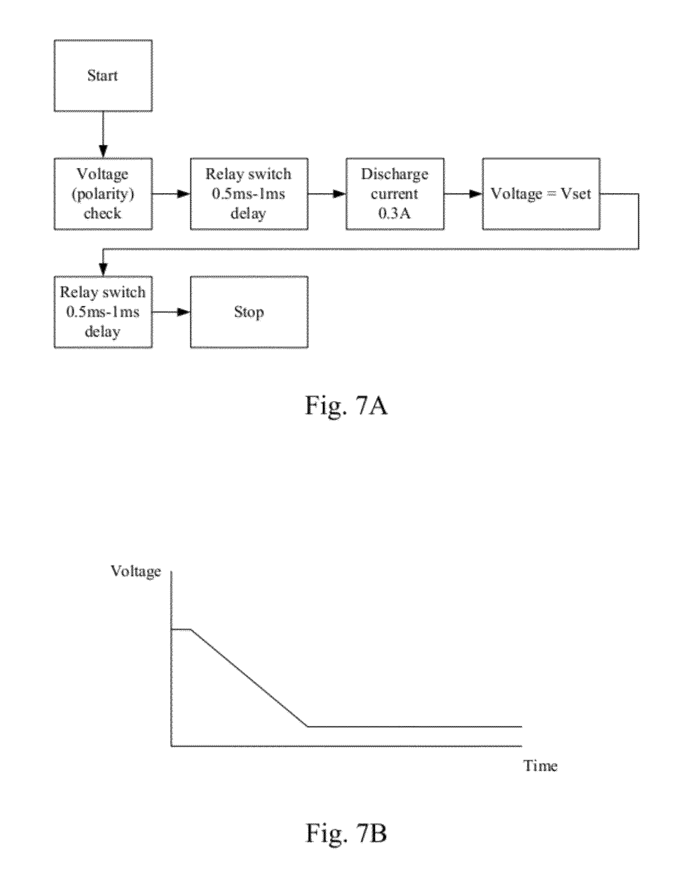

On the contrary, when the discharge device 14 depicted in FIG. 1 is adapted, the constant discharge current starts to discharge the device under test 2 after the polarity of the voltage of the capacitor is determined until the voltage drops to a specific level (Vset), as shown FIG. 7A, which is the flow chart of the discharge process when the discharge device 14 is adapted. The decrease of the voltage is a liner process as depicted in FIG. 7B due to the constant discharge current. The total discharge time is (capacitance×voltage)/(average current), which is (100×24)/0.3=8 ms.

Consequently, the constant current discharge units can drain constant currents from the device under test 2 and the power supply modules 10 to speed up the discharge process in the test flow. Further, unlike the sequential discharge process of the resistor switch, the constant current discharge units can perform the discharge process on the pin groups with different logic level in parallel. The total time of the test flow is thus shortened.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A discharge device adapted in a test system comprising:
at least one constant current discharge unit disposed in at least one power supply module or a test instrument of the test system; and
a control module to control the constant current discharge unit to drain a constant current from the device under test through the test instrument or from the power supply module to perform a discharge process when any one of the on-power test procedures is finished.

2. The discharge device of claim 1, wherein the constant current discharge unit is a floating zero volt active load.

3. The discharge device of claim 1, wherein the control module further monitors a voltage of the device under test or the power supply module such that the control module stops the discharge process when the voltage is not larger than a specific level.

4. The discharge device of claim 1, wherein the control module controls a value of the constant current drained by the constant current discharge unit.

5. A test system comprising:
at least one power supply module to supply power to a device under test;
a test instrument connected to the device under test to perform a plurality of on-power test procedures on the device under test; and
a discharge device comprising:
at least one first constant current discharge unit disposed in the test instrument;
at least one second constant current discharge unit disposed in the power supply module; and
a control module to control the first and the second constant current discharge units to drain a constant current from the device under test and the power supply module respectively to perform a discharge process when any one of the on-power test procedures is finished.

6. The test system of claim 5, wherein the first constant current discharge unit and the second constant current discharge unit are a floating zero volt active load respectively.

7. The test system of claim 5, wherein the control module further monitors a voltage of the power supply module such that the control module controls the second constant current discharge unit to stop the discharge process when the voltage is not larger than a specific level.

8. The test system of claim 5, wherein the control module further monitors a voltage of the device under test such that the control module controls the first constant current discharge unit to stop the discharge process when the voltage is not larger than a specific level.

9. The test system of claim 5, the control module controls a value of the constant current drained by the first and the second constant current discharge units respectively.

10. The test system of claim 5, wherein the number of the first constant current discharge units is substantially at least two and the at least two first constant current discharge units are connected to at least two first pin groups of the device under test through the test instrument.

11. The test system of claim 10, wherein the at least two first pin groups have different logic voltage levels.

12. The test system of claim 11, wherein the logic voltage levels are positive.

13. The test system of claim 5, wherein the discharge device further comprises a resistor switch discharge device connected to at least one second pin group of the device under test through the test instrument, wherein the at least one second pin group has a negative logic voltage level.

14. The test system of claim 5, wherein the test instrument comprises a switching board and a backplane such that the first constant current discharge unit is connected to the backplane to be further connected to the device under test through the switching board.

15. The test system of claim 14, wherein the switching board comprises a relay matrix and the backplane comprises a system bus, where the system bus is connected to the relay matrix.
